(19) United States
(12) Patent Application Publication
(10) Pub. No.: US 2025/0048845 A1
(43) Pub. Date: Feb. 6, 2025

(54) SI-AP OVERHANG DISPLAY

(71) Applicant: Applied Materials, Inc., Santa Clara, CA (US)

(72) Inventors: Jungmin LEE, Santa Clara, CA (US); Dieter HAAS, Santa Clara, CA (US); Yu-hsin LIN, Zhubei City (TW); Chung-chia CHEN, Hsinchu City (TW); Ji Young CHOUNG, Hwaseong-si (KR)

(21) Appl. No.: 18/774,523

(22) Filed: Jul. 16, 2024

Related U.S. Application Data
(60) Provisional application No. 63/517,065, filed on Aug. 1, 2023.

(51) Int. Cl. H10K 59/122

(52) U.S. Cl. CPC H10K 59/122

(57) ABSTRACT

The present disclosure provides sub-pixels. The sub-pixels include a plurality of pixel structures separating a plurality of anodes. The plurality of pixel structures are disposed over a substrate. A plurality of overhang structures are disposed over the plurality of pixel structures. Each overhang structure of the plurality of overhang structures include an upper portion including amorphous silicon disposed over a lower portion including germanium. A bottom surface of the upper portion extends laterally past an upper surface of the lower portion. An organic light emitting diode (OLED) material is disposed over an upper surface of the plurality of anodes and an upper surface of the plurality of pixel structures. A cathode is disposed over the OLED material and the upper surface of the plurality of pixel structures.

### CROSS-REFERENCE TO RELATED APPLICATIONS

This application claims priority to U.S. Provisional Patent Application Ser. No. 63/517,065, filed on Aug. 1, 2023, which is herein incorporated by reference in its entirety.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits to increase pixel-per-inch and provide improved OLED performance.

### SUMMARY

In an aspect, the present disclosure provides a sub-pixel. The sub-pixel includes a plurality of pixel structures separating a plurality of anodes. The plurality of pixel structures are disposed over a substrate. A plurality of overhang structures are disposed over the plurality of pixel structures. Each overhang structure of the plurality of overhang structures include an upper portion including amorphous silicon disposed over a lower portion including germanium. A bottom surface of the upper portion extends laterally past an upper surface of the lower portion. An organic light emitting diode (OLED) material is disposed over an upper surface of the plurality of anodes and an upper surface of the plurality of pixel structures. A cathode is disposed over the OLED material and the upper surface of the plurality of pixel structures.

In another aspect, the present disclosure provides a sub-pixel. The sub-pixel includes a plurality of pixel structures separating a plurality of anodes. The plurality of pixel structures are disposed over a substrate. A plurality of overhang structures are disposed over the plurality of pixel structures. Each overhang structure of the plurality of overhang structures include an upper portion including gallium arsenide disposed over a lower portion including amorphous silicon. A bottom surface of the upper portion extends laterally past an upper surface of the lower portion. An organic light emitting diode (OLED) material is disposed over an upper surface of the plurality of anodes and an upper surface of the plurality of pixel structures. A cathode is disposed over the OLED material and the upper surface of the plurality of pixel structures.

In another aspect, the present disclosure provides a sub-pixel. The sub-pixel includes a plurality of pixel structures separating a plurality of anodes. The plurality of pixel structures are disposed over a substrate. A plurality of overhang structures are disposed over the plurality of pixel structures. Each overhang structure of the plurality of overhang structures include an upper portion including germanium disposed over a lower portion including silicon nitride. A bottom surface of the upper portion extends laterally past an upper surface of the lower portion. An organic light emitting diode (OLED) material is disposed over an upper surface of the plurality of anodes and an upper surface of the plurality of pixel structures. A cathode is disposed over the OLED material and the upper surface of the plurality of pixel structures.

In another aspect, the present disclosure provides a sub-pixel. The sub-pixel includes a plurality of pixel structures separating a plurality of anodes. The plurality of pixel structures are disposed over a substrate. A plurality of overhang structures are disposed over the plurality of pixel structures. Each overhang structure of the plurality of overhang structures include an upper portion including gold disposed over a lower portion including amorphous silicon or silicon nitride. A bottom surface of the upper portion extends laterally past an upper surface of the lower portion. An organic light emitting diode (OLED) material is disposed over an upper surface of the plurality of anodes and an upper surface of the plurality of pixel structures. A cathode is disposed over the OLED material and the upper surface of the plurality of pixel structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit, according to embodiments of the present disclosure.

FIG. 1B is a schematic, cross-sectional view of a sub-pixel circuit at section line 1B-1B, according to embodiments of the present disclosure.

FIG. 1C is a schematic, cross-sectional view of a sub-pixel circuit having a line-type architecture at section line 1C-1C, according to embodiments of the present disclosure.

FIG. 2 is a schematic, cross-sectional view of an overhang structure, according to embodiments of the present disclosure.

FIG. 3 is a flow diagram of a method for forming a sub-pixel, according to embodiments of the present disclosure.

FIGS. 4A-4R are schematic, cross-sectional views of a substrate during a method of forming a sub-pixel, according to embodiments of the present disclosure.

FIG. 5 is a schematic cross-sectional view of a sub-pixel circuit, according to embodiments of the present disclosure.

FIG. 6 is a flow diagram of a method for forming a sub-pixel, according to embodiments of the present disclosure.

FIGS. 7A-7K are schematic, cross-sectional views of a substrate during a method of forming a sub-pixel, according to embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced overhang structures having inorganic upper portions and inorganic lower portions to allow for enhanced etch selectivity as well as reduced critical dimensions, e.g., about 1 nm to about 500 nm, between adjacent overhang structures. The overhang structures can allow for about 6000 pixels per inch (ppi) in a display.

Each of the embodiments described herein of the sub-pixel circuit include a plurality of sub-pixels with each of the sub-pixels are defined by adjacent overhang structures that are permanent to the sub-pixel circuit. While the figures depict one and/or two sub-pixels with each sub-pixel defined by adjacent overhang structures, the sub-pixel circuit of the embodiments described herein include a plurality of sub-pixels, such as one or more subpixels. Each sub-pixel has OLED materials configured to emit a white, red, green, blue or other color light when energized, e.g., the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit and include at least an upper portion disposed over a lower portion. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and cathode. In some instances, an encapsulation layer may be disposed via evaporation deposition. In embodiments including one or more capping layers, the capping layers are disposed between the cathode and the encapsulation layer. The overhang structures and the evaporation angle set by the evaporation source define the deposition angles, e.g., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

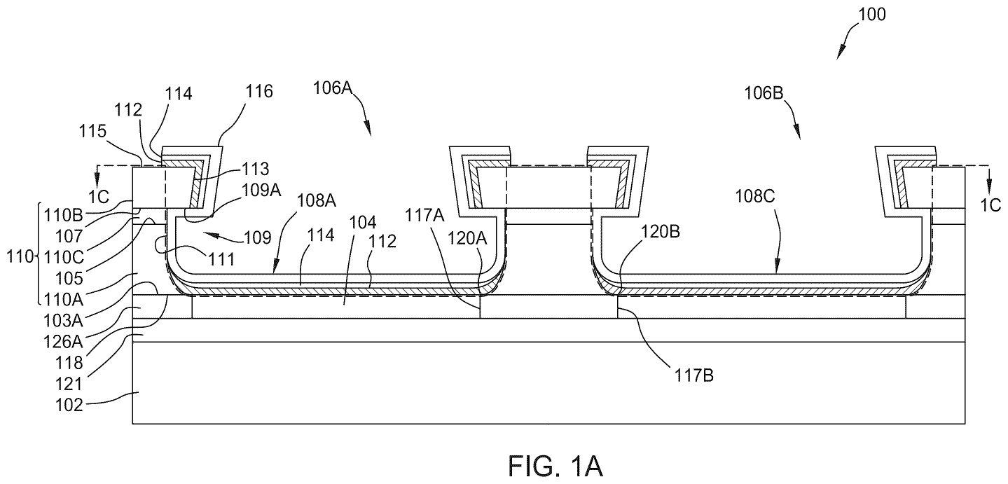

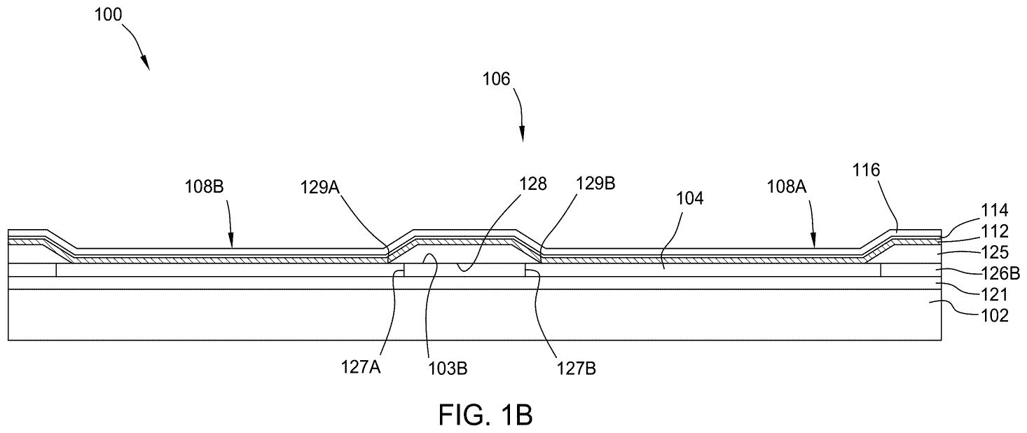

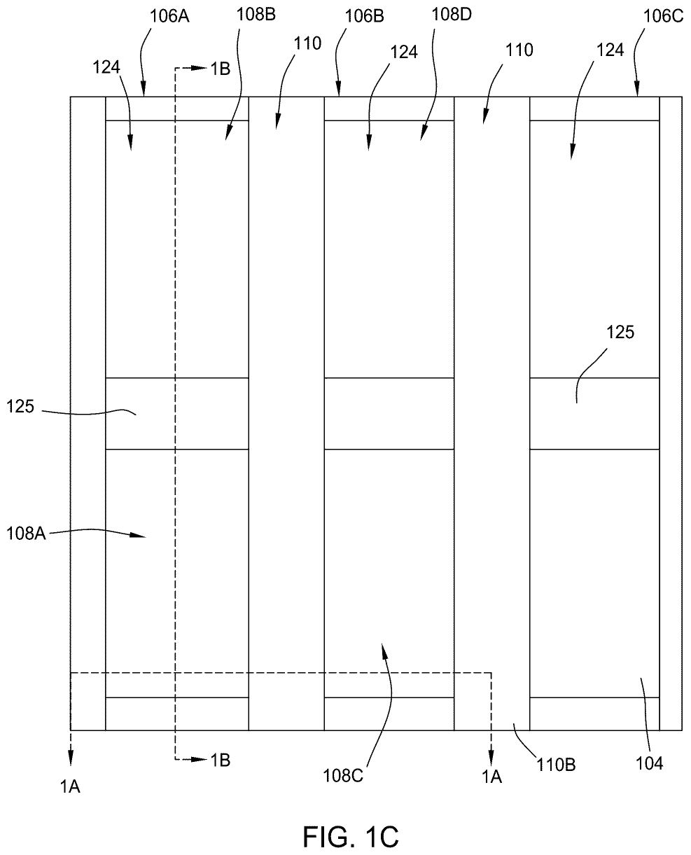

FIG. 1A is a schematic, cross-sectional view of a sub-pixel circuit 100 according to embodiments. The cross-sectional view of FIG. 1A is taken along section line 1A-1A of FIG. 1C (e.g., a pixel plane). FIG. 1B is a schematic, cross-sectional view of a sub-pixel circuit 100 according to embodiments. The cross-sectional view of FIG. 1B is taken along section line 1B-1B of FIG. 1C (e.g., a line plane). The sub-pixel circuit 100 includes a substrate 102. A base layer 121 may be patterned over the substrate 102. The base layer 121 includes, but is not limited to, a CMOS layer. Metal-containing layers (e.g., anodes 104) may be patterned on the base layer 121 and are defined by adjacent pixel isolation structures (PIS), e.g., the first PIS 126A and second PIS 126B disposed on the substrate 102. In one embodiment, the anodes 104 are pre-patterned on the base layer 121, e.g., the base layer 121 is pre-patterned with anodes 104 of indium tin oxide (ITO). The anodes 104 may be disposed on the substrate 102. The anodes 104 are configured to operate as anodes of respective sub-pixels. In one embodiment, the anode 104 is a layer stack of a first transparent conductive oxide (TCO) layer, a second metal-containing layer disposed on the first TCO layer, and a third TCO layer disposed on the second metal-containing layer. The anodes 104 include, but are not limited to, chromium, titanium, gold, silver, copper, aluminum, ITO, a combination thereof, or other suitably conductive materials.

The PIS, e.g., the first PIS 126A and second PIS 126B are disposed over the substrate 102. The first PIS 126A and second PIS 126B may be disposed on the base layer 121. The first PIS 126A is disposed along the line plane. The line plane extends along a first direction. The second PIS 126B is disposed along the pixel plane. The pixel plane extends along a second direction. The first direction is perpendicular to the second direction. The first PIS 126A and second PIS 126B include one of an organic material, an organic material with an inorganic coating disposed thereover, or an inorganic material. The organic material of the first PIS 126A and second PIS 126B includes, but is not limited to, polyimides. The inorganic material of the first PIS 126A and second PIS 126B includes, but is not limited to, silicon oxide (SiO₂), silicon nitride (Si₃N₄), silicon oxynitride (Si₂N₂O), magnesium fluoride (MgF₂), or combinations thereof. Adjacent first PIS and second PIS define a respective sub-pixel and expose the anode 104 of the respective sub-pixel circuit.

The sub-pixel circuit 100 has a plurality of sub-pixel lines (e.g., first sub-pixel line 106A and second sub-pixel line 106B). The sub-pixel lines are adjacent to each other along the pixel plane. Each sub-pixel line includes at least two sub-pixels, e.g., the first sub-pixel line 106A includes a first sub-pixel 108A and a second sub-pixel 108B and the second sub-pixel line 106B includes a third sub-pixel 108C and a fourth sub-pixel 108D. The first sub-pixel 108A and the second sub-pixel 108B are aligned along the line plane. The third sub-pixel 108C and the fourth sub-pixel 108D are aligned along the line plane. While FIG. 1A depicts the first sub-pixel line 106A and the second sub-pixel line 106B, the sub-pixel circuit 100 of the embodiments described herein may include two or more sub-pixel lines, such as a third sub-pixel line 106C (as shown in FIG. 1B) and a fourth sub-pixel. Each sub-pixel line has OLED materials configured to emit a white, red, green, blue or other color light when energized, e.g., the OLED materials of the first sub-pixel line 106A emits a red light when energized, the OLED materials of the second sub-pixel line 106B emits a green light when energized, the OLED materials of a third sub-pixel line 106C emits a blue light when energized, and the OLED materials of a fourth sub-pixel emits another color light when energized. The OLED materials within a pixel line may be configured to emit the same color light when energized, e.g., the OLED materials of the first sub-pixel 108A and the second sub-pixel 108B of the first sub-pixel line 106A emit a red light when energized and the OLED materials of the third sub-pixel 108C and the fourth sub-pixel 108D of the second sub-pixel line 106B emit a green light when energized.

Each sub-pixel line includes overhang structures 110, with adjacent sub-pixel lines sharing adjacent overhang structures in the pixel plane. The overhang structures 110 are permanent to the sub-pixel circuit 100. The overhang structures 110 further define each sub-pixel line of the sub-pixel circuit 100. Each overhang structure includes adjacent overhangs 109. The adjacent overhangs 109 are defined by an overhang extension 109A of an upper portion 110B extending laterally past an upper surface 105 of a lower portion 110A. The lower portion 110A is disposed over an upper surface 103A of the first PIS 126A. A first endpoint 120A of a bottom surface 118 of the lower portion 110A may extend to or past a first edge 117A of the first PIS 126A. A second endpoint 120B of the bottom surface of the lower portion 110A may extend to or past a second edge 117B the first PIS 126A. The upper portion 110B is disposed over the lower portion 110A. The upper portion 110B may be disposed on the upper surface 105 of the lower portion 110A.

In one embodiment, the overhang structures 110 include the upper portion 110B of a first non-conductive inorganic material and the lower portion 110A of a second non-conductive inorganic material. The first non-conductive inorganic material is different than the second non-conductive inorganic material. The non-conductive inorganic materials of the upper portion 110B can include germanium (Ge), amorphous silicon (a-Si), gallium arsenide (GaAs), a group III element, a group IV element, a III-V compound, or a combination thereof. The non-conductive inorganic materials of the lower portion 110A can include amorphous silicon (a-Si), germanium (Ge), titanium (Ti), silicon nitride (Si₃N₄), silicon oxide (SiO₂), silicon oxynitride (Si₂N₂O), gallium arsenide (GaAs), a group III element, a group IV element, a III-V compound, or a combination thereof or combinations thereof.

In at least one embodiment, the overhang structures 110 include an upper portion 110B of amorphous silicon and a lower portion 110A of germanium. Without being bound by theory, an upper portion 110B of amorphous silicon and a lower portion 110A of germanium can provide enhanced etch selectivity compared to conventional overhang structures.

In at least one embodiment, the overhang structures 110 include an upper portion 110B of gallium arsenide and a lower portion 110A of amorphous silicon. Without being bound by theory, an upper portion 110B of gallium arsenide and a lower portion 110A of amorphous silicon can provide enhanced etch selectivity compared to conventional overhang structures.

In at least one embodiment, the overhang structures 110 include an upper portion 110B of germanium and a lower portion 110A of silicon nitride. Without being bound by theory, an upper portion 110B of germanium and a lower portion 110A of silicon nitride can provide enhanced etch selectivity compared to conventional overhang structures.

In one embodiment, the overhang structures 110 include the upper portion 110B of a conductive inorganic material and the lower portion 110A of the second non-conductive inorganic material. The conductive materials of the upper portion 110B include a gold (Au), copper (Cu), aluminum (Al), aluminum neodymium (AlNd), molybdenum (Mo), molybdenum tungsten (MoW), or combinations thereof. The non-conductive materials of the lower portion 110A include amorphous silicon (a-Si), germanium (Ge), titanium (Ti), silicon nitride (Si₃N₄), silicon oxide (SiO₂), silicon oxynitride (Si₂N₂O), gallium arsenide (GaAs), a group III element, a group IV element, a III-V compound, or combinations thereof.

In at least one embodiment, the overhang structures 110 include an upper portion 110B of gold and a lower portion 110A of amorphous silicon and/or silicon nitride. For example, the overhang structures 110 can include an upper portion 110B of gold and a lower portion 110A of amorphous silicon. As a further example, the overhang structures 110 can include an upper portion 110B of gold and a lower portion 110A of silicon nitride. Without being bound by theory, an upper portion 110B of gold and a lower portion 110A of amorphous silicon and/or silicon nitride can provide enhanced etch selectivity compared to conventional overhang structures.

The adjacent overhangs 109 are defined by the overhang extension 109A. At least a bottom surface 107 of the upper portion 110B is wider than the upper surface 105 of the lower portion 110A to form the overhang extension 109A. The overhang extension 109A of the upper portion 110B forms the adjacent overhangs 109 and allows for the upper portion 110B to shadow the lower portion 110A. The shadowing of the adjacent overhangs 109 provides for evaporation deposition of an OLED material 112 and a cathode 114. The OLED material 112 may include one or more of a HIL, a HTL, an EML, and an ETL. The OLED material 112 is disposed over and in contact with the anode 104. The OLED material 112 is disposed under adjacent overhangs 109 and may contact a sidewall 111 of the lower portion 110A. In one embodiment, the OLED material 112 is different from the material of the lower portion 110A, the upper portion 110B, and the intermediate structure 110C. The cathode 114 is disposed over the OLED material 112 and extends under the adjacent overhangs 109. The cathode 114 may extend past an endpoint of the OLED material 112. The cathode 114 may contact the sidewall 111 of the lower portion 110A. The overhang structures 110 and an evaporation angle set by an evaporation source define deposition angles, e.g., the overhang structures provide for a shadowing effect during evaporation deposition with the evaporation angle set by the evaporation source.

The cathode 114 includes a conductive material, such as a metal, e.g., the cathode 114 includes, but is not limited to, silver, magnesium, chromium, titanium, aluminum, ITO, or a combination thereof. In one embodiment, material of the cathode 114 is different from the material of the lower portion 110A, the upper portion 110B, and intermediate structure 110C. In some embodiments, e.g., as shown in FIG. 1A as applied to the sub-pixel circuit 100, the OLED material 112 and the cathode 114 are disposed over a sidewall 113 of the upper portion 110B of the overhang structures 110 in the pixel plane. In other embodiments, the OLED material 112 and the cathode 114 are disposed over an upper surface 115 of the upper portion 110B of the overhang structures 110 in the pixel plane. In still other embodiments, the OLED material 112 and the cathode 114 end on the sidewall 111 of the lower portion 110A, e.g., are not disposed over the sidewall 113 of the upper portion 110B or the upper surface 115 of the upper portion 110B in the pixel plane.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhangs and along a sidewall 111 of each of the lower portion 110A and the upper portion 110B. The encapsulation layer 116 is disposed over the cathode 114 and extends at least to contact the cathode 114 over the sidewall 111 of the lower portion 110A in the pixel plane. In some embodiments, the encapsulation layer 116 extends to contact the sidewall 111 of the lower portion 110A. In the illustrated embodiments as shown in FIGS. 1A and 1B, the encapsulation layer 116 extends to contact the upper portion 110B at an underside surface of the overhang extension 109A, the sidewall 113 of the upper portion 110B, and the upper surface 115 of the upper portion 110B. In some embodiments, the encapsulation layer 116 extends to contact the upper portion 110B at an underside surface of the overhang extension 109A and to be disposed over the OLED material 112 and the cathode 114 when the OLED material 112 and the cathode 114 are disposed over the sidewall 113 and upper surface 115 of the upper portion 110B. In some embodiments, the encapsulation layer 116 ends at the sidewall 111 of the lower portion 110A, e.g., is not disposed over the sidewall 113 of the upper portion 110B, the upper surface 115 of the upper portion 110B, or the underside surface of the overhang extension 109A of the overhang structures 110. The encapsulation layer 116 includes the non-conductive inorganic material, such as the silicon-containing material. The silicon-containing material may include Si₃N₄ containing materials.

Each sub-pixel line includes adjacent separation structures, with adjacent sub-pixels sharing the adjacent separation structures in the line plane. The separation structures 125 are permanent to the sub-pixel circuit 100. The separation structures 125 further define each sub-pixel of the sub-pixel line of the sub-pixel circuit 100. The separation structures 125 are disposed over an upper surface 103B of the pixel structures. A first endpoint 129A of a bottom surface 128 of the separation structures 125 may extend to or past a first edge 127A of the pixel structures. A second endpoint 129B of the bottom surface 128 of the separation structures 125 may extend to or past a second edge 127B the pixel structures.

The OLED material 112 is disposed over and in contact with the anode 104 and the separation structure 125 in the line plane. The cathode 114 is disposed over the OLED material 112 in the line plane. The encapsulation layer 116 is disposed over the cathode 114 in the line plane. As shown in FIG. 1B, the OLED material 112, the cathode 114, and the encapsulation layer 116 maintain continuity along the length of the line plane in order to apply current across each sub-pixel 106.

In embodiments including one or more capping layers, the capping layers are disposed between the cathode 114 and the encapsulation layer 116, e.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the sub-pixel circuit 100 further includes at least a global passivation layer disposed over the overhang structure 110 and the encapsulation layer 116. In yet another embodiment, the sub-pixel includes an intermediate passivation layer disposed over the overhang structures 110 of each of the sub-pixels 106, and disposed between the encapsulation layer 116 and the global passivation layer.

FIG. 1C is a schematic, cross-sectional view of a sub-pixel circuit 100 having a line-type architecture according to embodiments. The top sectional views of FIG. 1C is taken along section line 1C-1C of FIG. 1A. The line-type architecture includes a plurality of pixel openings 124. Each of pixel opening 124 is abutted by overhang structures 110 in the pixel plane and separation structure 125 in the line plane, as shown in FIG. 1A and FIG. 1B, which define each of the sub-pixel line and sub-pixel of the line-type architecture.

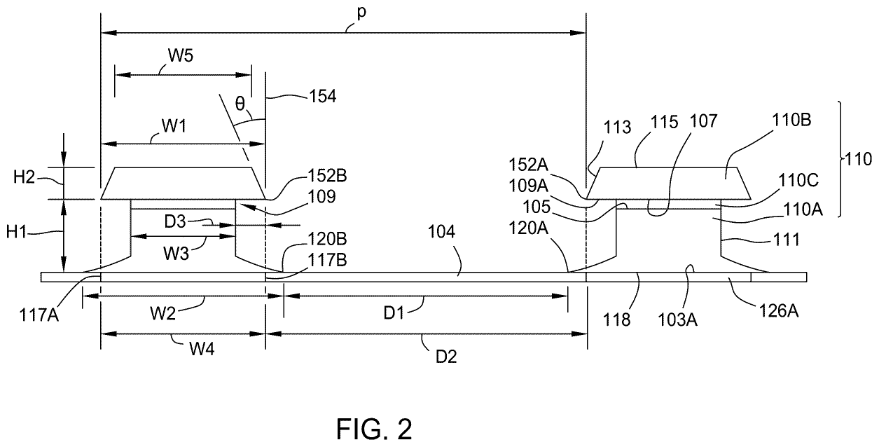

FIG. 2 is a schematic, cross-sectional view of an overhang structure 110.

The overhang structure 110 is shown without the OLED material 112, the cathode 114, the encapsulation layer 116, the base layer 121, or the substrate 102. The upper surface 115 of the upper portion 110B has a width W1 from a first underside edge 152A to a second underside edge 152B. The width W1 is from about 0.4 μm to about 1.2 μm. The bottom surface 118 of the lower portion 110A has a width W2 from the first endpoint 120A of the bottom surface 118 to the second endpoint 120B of the bottom surface 118. The width W2 is from about 0.2 μm to about 1.4 μm. The upper surface 105 of the lower portion 110A has a width W3. The width W3 is from 0.2 μm to about 0.8 μm. The first PIS 126A has a width W4 from the first edge 117A to the second edge 117B. The width W4 is from 0.4 μm to about 1.2 μm. The width W4 and the width W1 may be equal or approximately equal. The upper surface 115 of the upper portion 110B has a width W5. The width W5 is from about 0.2 μm to about 1.0 μm.

The overhang structures 110 has a height H1 from the upper surface 103A of the first PIS 126A to the bottom surface 107 of the upper portion 110B. The height H1 is from about 0.1 μm to about 0.5 μm. The height H1 may be the height of the lower portion 110A. The upper portion 110B has a height H2 from the bottom surface 107 to the upper surface 115. The height H2 is from about 0.15 μm to about 0.25 μm. A width of the upper surface 115 of the upper portion 110B is less than the width of the bottom surface 107 of the upper portion 110B. The sidewall 113 of the upper portion 110B has an angle θ with respect to an overhang vector 154 of about 15° to about 45°.

The sub-pixel circuit 100 has a pitch p. The pitch p is the distance from a first edge 117A of the first PIS 126A to the first edge 117A of an adjacent first PIS. The pitch p is from about 2 μm to about 8 μm. The sub-pixel circuit 100 has a distance D1 from the second endpoint 120B of the upper portion 110B of an overhang structure 110 to a first endpoint 120A of the upper portion 110B of an adjacent overhang structure. The distance D1 is from about 2 μm to about 6 μm. The sub-pixel circuit 100 has a distance D2 from the second edge 117B of the first PIS 126A to the first edge 117A of the first PIS 126A of an adjacent overhang structure (e.g., a width of the anode 104). The distance D2 is from 2 μm to about 6 μm. The distance D1 and the distance D2 may be equal or approximately equal. The overhang structure 110 has a distance D3 from a first underside edge 152A or a second underside edge 152B of the upper portion 110B to the sidewall 111 of the lower portion 110A. The distance D3 is less than about 0.15 μm.

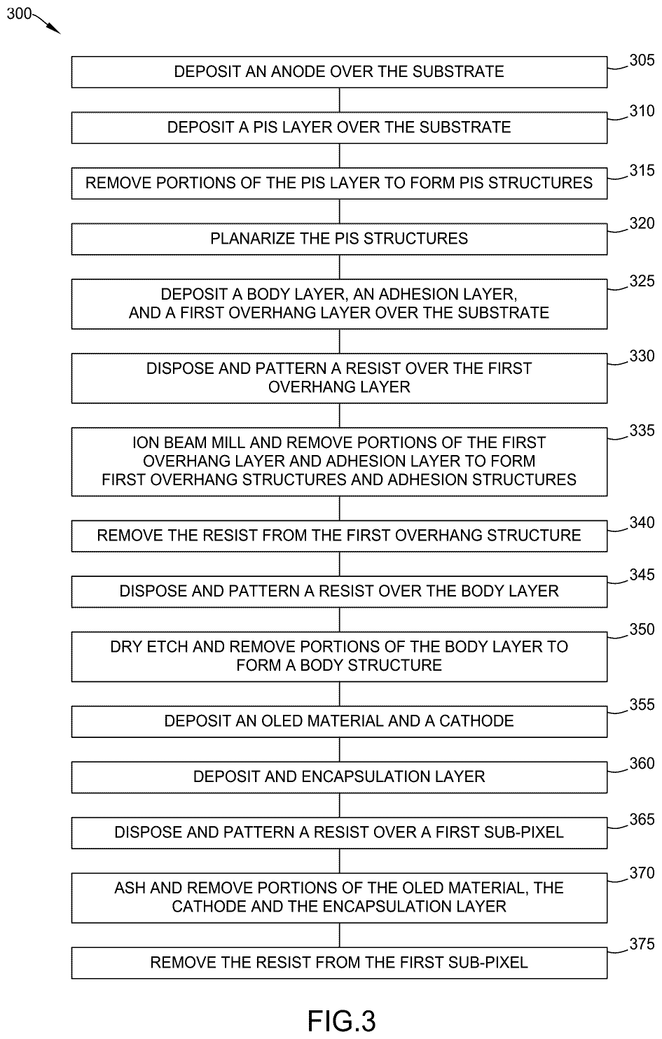

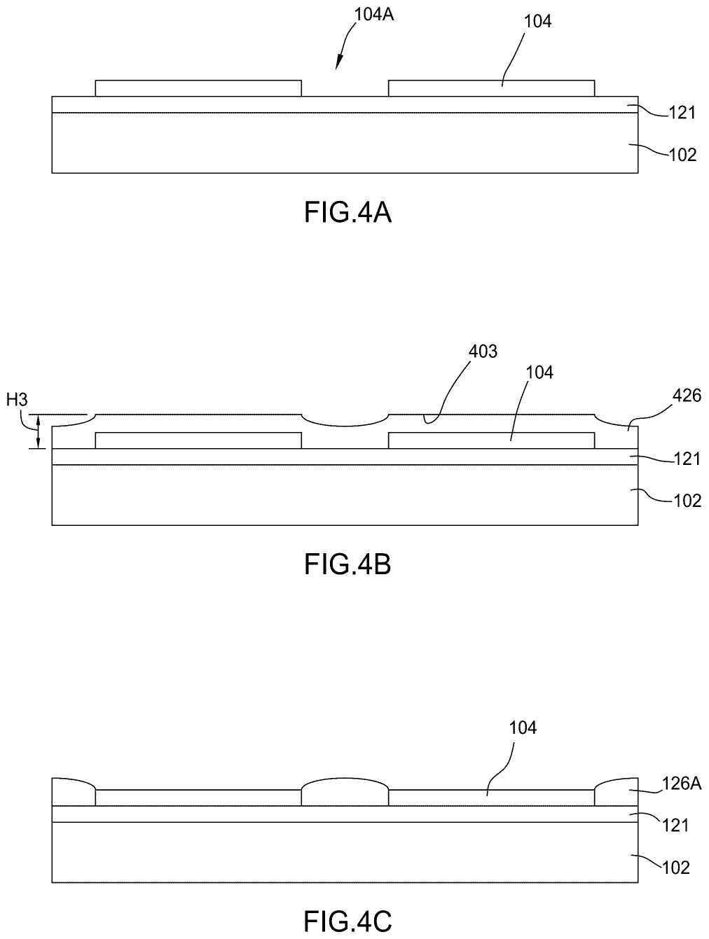

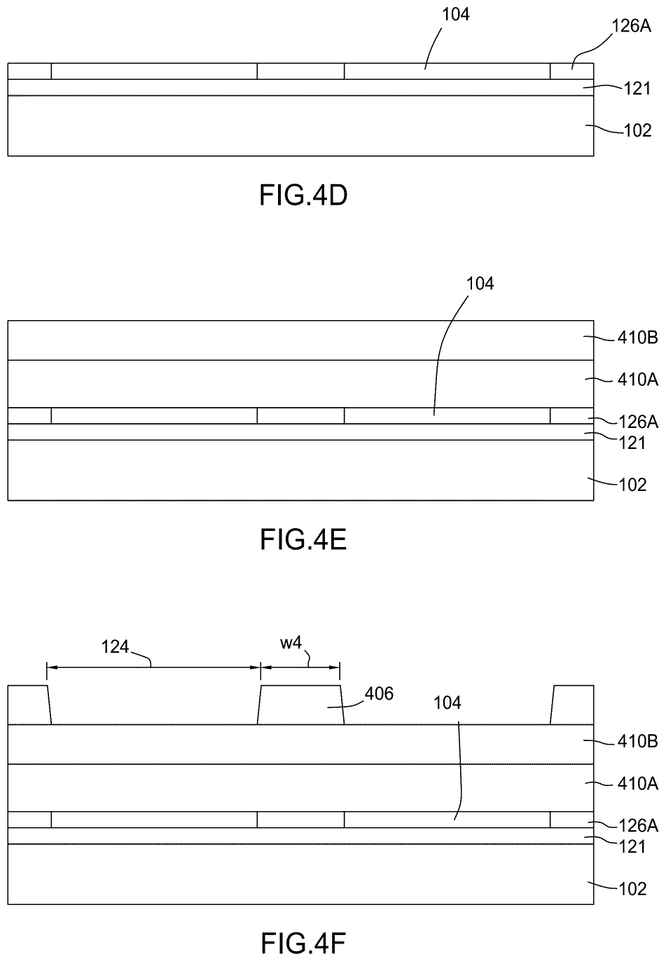

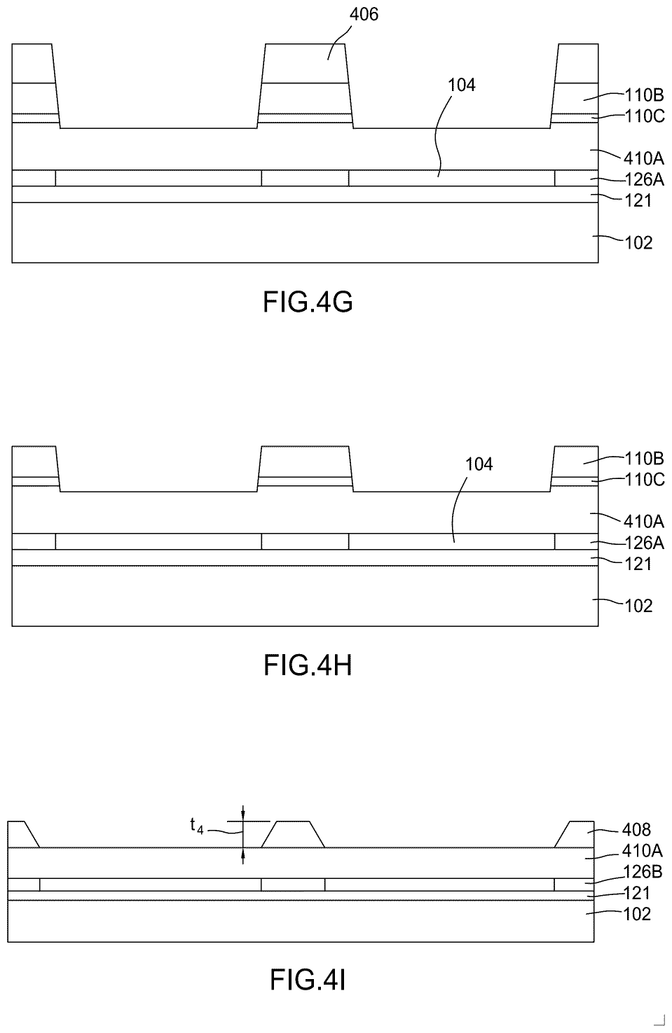

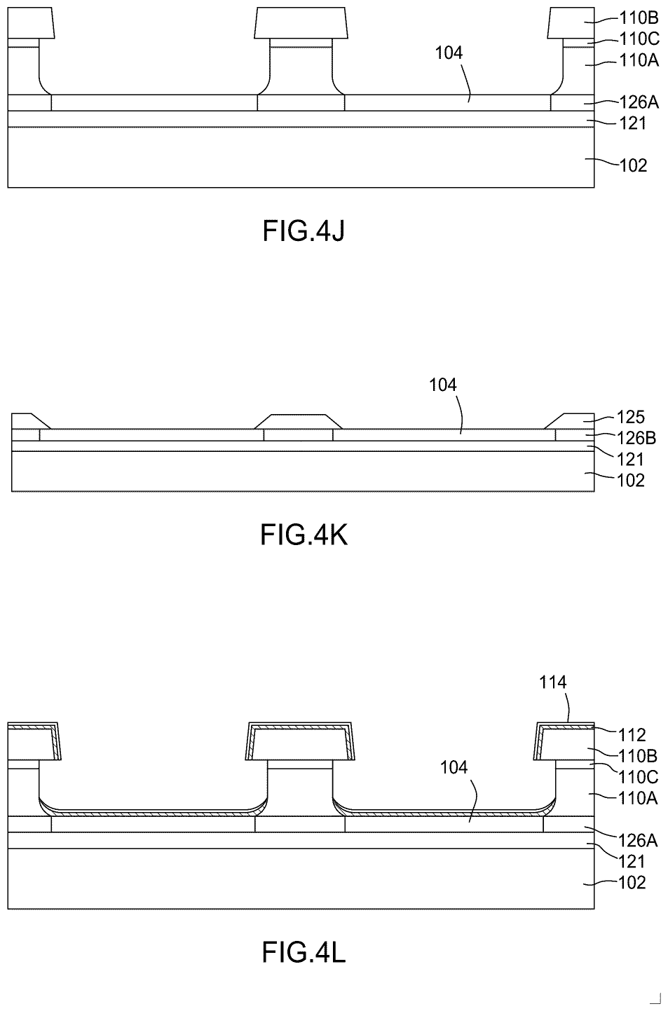

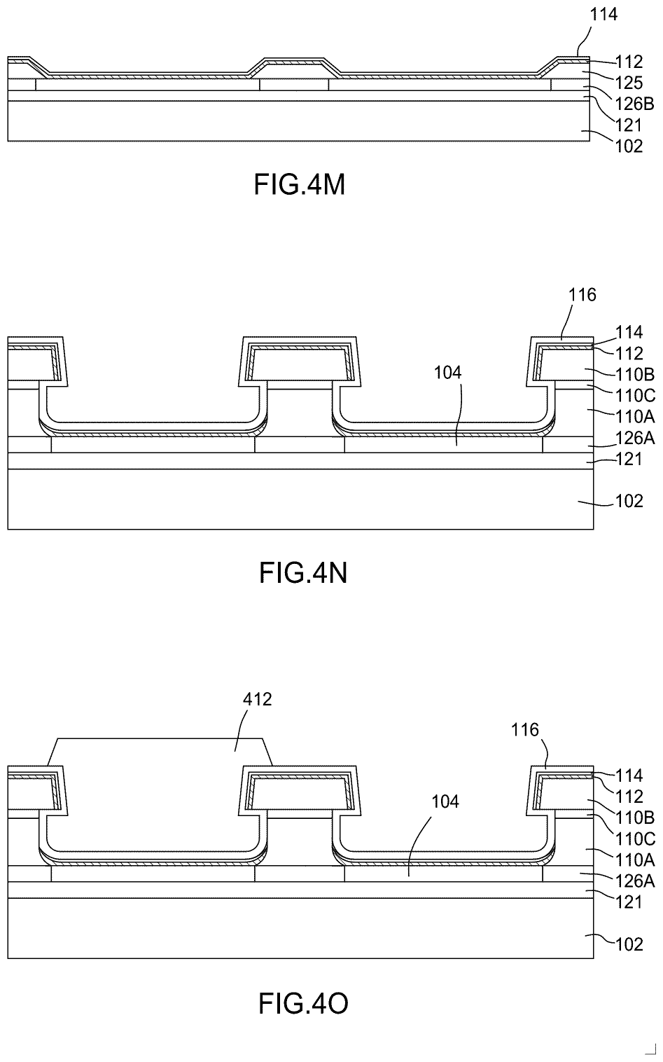

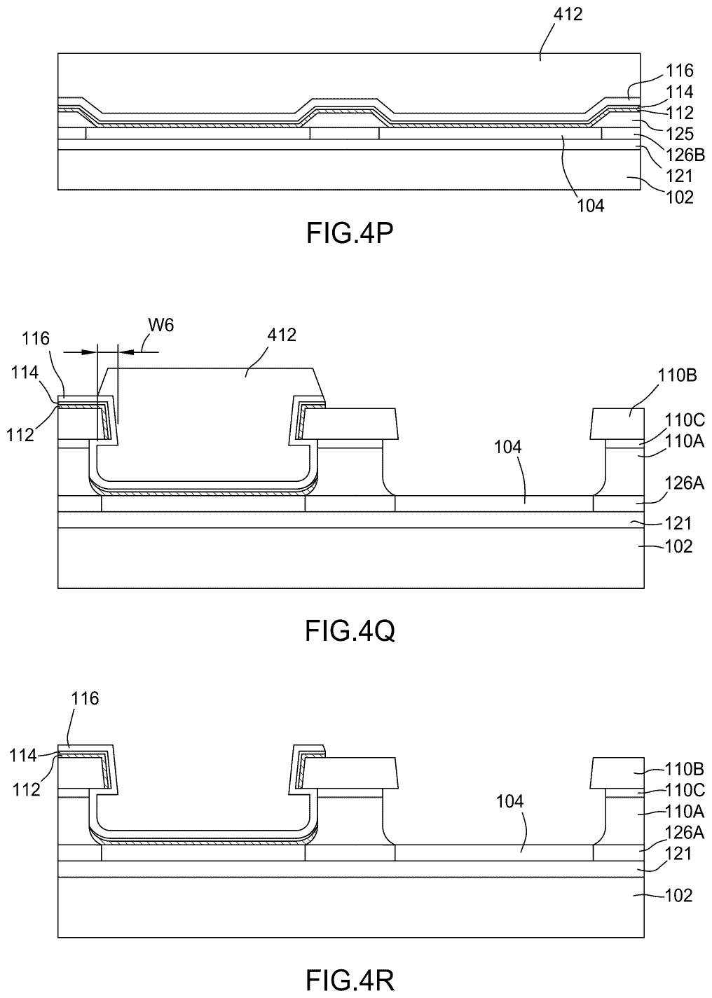

FIG. 3 is a flow diagram of a method 300 for forming a sub-pixel circuit 100 according to embodiment. FIG. 4A-4R are schematic, cross-sectional views of a substrate 102 during a method 300 for forming a sub-pixel circuit 100 according to embodiments described herein.

At operation 305, as shown in FIG. 4A (along the pixel plane), an anode 104 is deposited over the substrate 102. The anode 104 may be deposited on the substrate 102. In another embodiment, the anode 104 is deposited on a base layer 121. The base layer 121 is disposed on the substrate 102. The anode 104 may be deposited using metal-organic decomposition (MOD). An anode gap 104A separates the anode 104 from an adjacent anode.

At operation 310, as shown in FIG. 4B (along the pixel plane), a PIS layer 426 is deposited over the substrate 102. The PIS layer 426 may be deposited on the anode 104 and on the base layer 121 in the anode gap 104A. A height H3 from the base layer 121 to an upper surface 403 of the PIS layer 426 is from about 400 nm to about 700 nm.

At operation 315, as shown in FIG. 4C (along the pixel plane), portions of the PIS layer 426 are removed. The PIS layer 426 may be removed by a wet etch or dry etch process. Operations 315 exposes the anode 104 and forms a plurality of pixel isolation structures (PIS) 126, e.g., a first PIS and a second PIS. At operation 320, as shown in FIG. 4D (along the pixel plane), the PIS 126 are planarized. The upper surface of the PIS 126 are aligned with the upper surface of the anode 104. The PIS 126 are cured at a temperature of about 140° C. to about 180° C. for about 10 minutes to about 20 minutes. The curing of the PIS 126 enables shrinkage of the PIS 126. The PIS 126 are planarized after curing. The planarization process of the PIS 126 may be performed using chemical-mechanical planarization (CMP).

At operation 325, as shown in FIG. 4E (along the pixel plane), a lower portion layer 410A and an upper portion layer 410B are deposited over the substrate 102. The lower portion layer 410A is deposited on the anode 104 and the PIS 126. The lower portion layer 410A has a thickness t₁ from about 0.1 μm to about 0.5 μm. The upper portion layer 410B is deposited on the lower portion layer 410A. The upper portion layer 410B is deposited using sputtering deposition. The upper portion layer 410B has a thickness t₃ from about 0.15 μm to about 0.25 μm.

At operation 330, as shown in FIG. 4F (along the pixel plane), a resist 406 is disposed and patterned. The resist 406 is disposed over the upper portion layer 410B. The resist 406 may have a width W₄ of about 0.8 μm to about 1.2 μm. The resist is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist 406 determines whether the resist is a positive resist or a negative resist. The portion of the upper portion layer 410B that has the resist 406 disposed thereon is patterned to form a pixel opening 124 of the line-type architecture of a first sub-pixel line 106A. The patterning is one of a photolithography, digital lithography process, or laser ablation process.

At operation 335, as shown in FIG. 4G (along the pixel plane), first overhang structures are formed by removing portions of the upper portion layer 410B exposed by the pixel opening 124. The upper portion layer 410B is removed by ion beam milling. In some embodiments, a portion of the lower portion layer 410A may be removed, e.g., about less than 50 nm of the lower portion layer 410A may be removed. Operation 335 forms the upper portion 110B. At operation 340, as shown in FIG. 4H (along the pixel plane), the resist 406 is removed from the upper portion 110B.

At operation 345, as shown in FIG. 4I (along the line plane), a resist 408 is disposed and patterned. The resist 408 is disposed over the lower portion layer 410A. The resist 408 has a thickness t₄ less than about 500 nm. The resist 408 has a taper from a bottom surface to an upper surface of about 40° to 50°, where the bottom surface of the resist 408 has a width that is greater than the upper surface of the resist 408. The resist 408 is a positive resist or a negative resist. The chemical composition of the resist 408 determine whether the resist 408 is a positive resist or a negative resist. The portion of the lower portion layer 410A that has the resist 408 disposed thereon is patterned to form a pixel opening 124 of the line-type architecture of the first sub-pixel line 106A. The patterning is one of a photolithography, digital lithography process, or laser ablation process.

At operation 350, as shown in FIG. 4J (along the pixel plane) and FIG. 4K (along the line plane), portions of the lower portion layer 410A exposed by the pixel opening 124 and the resist 408 are removed. The lower portion layer 410A and resist 408 are removed using dry etching. Operation 350 forms the lower portion 110A and the separation structures 125. The etch selectivity between the materials of the upper portion layer 410B corresponding to the upper portion 110B, the lower portion layer 410A corresponding to the lower portion 110A, and the etch processes to remove the exposed portions of the upper portion layer 410B and the lower portion layer 410A provide for the bottom surface 107 of the upper portion 110B being wider than the upper surface 105 of the lower portion 110A to form an overhang extension 109A of the adjacent overhangs 109. The shadowing of the adjacent overhangs 109 provide for evaporation deposition of the OLED material 112 and the cathode 114.

At operation 355, as shown in FIG. 4L (along pixel plane) and FIG. 4M (along the line plane), the OLED material 112 of the first sub-pixel line 106A and the cathode 114 are deposited. The OLED material 112 includes an HIL material. The shadowing of the adjacent overhangs 109 provides for evaporation deposition of each of the OLED material 112 and the cathode 114. The OLED material 112 and the cathode 114 may separate (e.g., may be non-continuous) along the pixel plane. The OLED material 112 and cathode 114 maintain continuity along the line plane, e.g., the OLED material 112 and the cathode 114 are disposed over the PIS 126 and/or the anode 104. The total thickness of the OLED material 112 and the cathode 114 is from about 100 nm to about 150 nm.

At operation 360, and encapsulation layer 116 is deposited, as shown in FIG. 4N (along the pixel plane). The encapsulation layer 116 is deposited over the cathode 114. A thickness of the encapsulation layer is from about 10 nm to about 50 nm. The shadowing of the adjacent overhangs 109 provides for evaporation deposition of the encapsulation layer 116. The encapsulation layer 116 may maintain continuity along the pixel plane and the line plane.

At operation 365, as shown in FIG. 4O (along the pixel plane) and FIG. 4P (along the line plane), a resist 412 is disposed in the first sub-pixel line 106A. The resist 412 is a positive resist or a negative resist. The chemical composition of the resist 412 determine whether the resist 412 is a positive resist or a negative resist. The resist 412 is patterned to protect the first sub-pixel line 106A from the subsequent etching processes. The resist 412 extends over the first sub-pixel 108A and the second sub-pixel 108B. The patterning is one of a photolithography, digital lithography process, or laser ablation process. The resist 412 has a width W6 extending over the upper surface 115 of the upper portion 110B of less than about 150 nm. The width W6 limit the overexposure of the OLED material 112 and cathode 114 disposed under the adjacent overhangs 109.

At operation 370, as shown in FIG. 4Q (along the pixel plane), portions of the OLED material 112, the cathode 114, and the encapsulation layer 116 exposed by the resist 412 are removed. The portions of the OLED material 112, the cathode 114, and the encapsulation layer 116 may be removed using ashing (e.g., O₂ ashing). The surface of the anode 104 may be cleaned using UV ozone (O₃) cleaning.

At operation 375, as shown in FIG. 4R (along the pixel plane), the resist 412 is removed from the first sub-pixel line 106A, leaving behind the first sub-pixel 108A and second sub-pixel 108B of the first sub-pixel line 106A. Operations 305 to 370 may be repeated until the desired number of sub-pixels are formed.

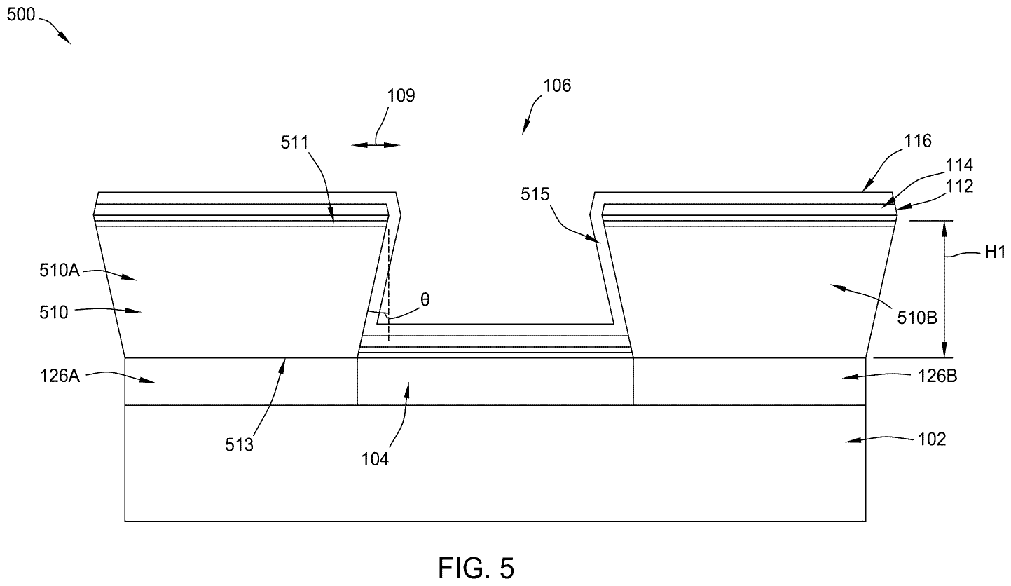

FIG. 5 is a schematic, cross-sectional view of a sub-pixel circuit 500 according to embodiments. The sub-pixel circuit 500 includes a substrate 102. A base layer may be patterned over the substrate 102. The base layer includes, but is not limited to, a CMOS layer. Metal-containing layers (e.g., anodes 104) are patterned on the substrate 102 and are defined by adjacent pixel isolation structures (PIS), e.g., the first PIS 126A and second PIS 126B disposed on the substrate 102. In one embodiment, the anodes 104 are pre-patterned on the base layer, e.g., the base layer is pre-patterned with anodes 104 of indium tin oxide (ITO). The anodes 104 are configured to operate as anodes of respective sub-pixels. In one embodiment, the anode is a layer stack of a first transparent conductive oxide (TCO) layer, a second metal-containing layer disposed on the first TCO layer, and a third TCO layer disposed on the second metal-containing layer. The anodes 104 include, but are not limited to, chromium, titanium, gold, silver, copper, aluminum, ITO, a combination thereof, or other suitably conductive materials.

The PIS, e.g., the first PIS 126A and second PIS 126B are disposed over the substrate 102. The first PIS 126A and second PIS 126B may be disposed on the base layer. The first PIS 126A and second PIS 126B include one of an organic material, an organic material with an inorganic coating disposed thereover, or an inorganic material. The organic material of the first PIS 126A and second PIS 126B can include polyimides. The inorganic material of the first PIS 126A and second PIS 126B includes, but is not limited to, silicon oxide (SiO₂), silicon nitride (Si₃N₄), silicon oxynitride (Si₂N₂O), magnesium fluoride (MgF₂), or combinations thereof. Adjacent first PIS and second PIS define a respective sub-pixel and expose the anode 104 of the respective sub-pixel circuit.

While FIG. 5 depicts the one sub-pixel 106, the sub-pixel circuit 500 of the embodiments described herein may include one or more sub-pixels, such as a second sub-pixel, a third sub-pixel, and a fourth sub-pixel. Each sub-pixel has OLED materials configured to emit a white, red, green, blue or other color light when energized, e.g., the OLED materials of the first sub-pixel emits a red light when energized, the OLED materials of the second sub-pixel emits a green light when energized, the OLED materials of a third sub-pixel emits a blue light when energized, and the OLED materials of a fourth sub-pixel emits another color light when energized. The OLED materials within a sub-pixel may be configured to emit the same color light when energized, e.g., the OLED materials of the first sub-pixel and the second sub-pixel emit a red light when energized and the OLED materials of the third sub-pixel and the fourth sub-pixel emit a green light when energized.

Each sub-pixel includes tapered structures 510 (e.g., a first tapered structure 510A and a second tapered structure 510B) with adjacent sub-pixel lines sharing adjacent tapered structures in the pixel plane. The tapered structures 510 are permanent to the sub-pixel circuit 500. The tapered structures 510 further define each sub-pixel line of the sub-pixel circuit 500. Each tapered structure includes a taper angle, θ, relative to an upper tapered structure surface 511. The taper angle, θ, creates an overhang extension of the tapered structure 510 such that an upper tapered structure surface 511 of the tapered structures 510 is wider than the lower tapered structure surface 513 of the tapered structures 510. The taper angle, θ, can be about 15° to about 45°. The tapered structures 510 have a height H1 from the upper surface 103A of the first PIS 126A to the upper tapered structure surface 511 of the tapered structures 510. The height H1 is from about 0.1 μm to about 0.5 μm.

In one embodiment, the tapered structures 510 include a non-conductive inorganic material. The non-conductive materials of the tapered structures 510 include amorphous silicon (a-Si), germanium (Ge), titanium (Ti), silicon nitride (Si₃N₄), silicon oxide (SiO₂), silicon oxynitride (Si₂N₂O), gallium arsenide (GaAs), a group III element, a group IV element, a III-V compound, or combinations thereof. For example, the tapered structures 510 can include amorphous silicon and/or silicon nitride. Without being bound by theory, tapered structures 510 including amorphous silicon and/or silicon nitride can provide enhanced etch selectivity compared to conventional overhang structures.

The tapered angle, θ, creates an overhang extension 109 of the tapered structure 510 to shadow the lower tapered structure surface 513 of the tapered structures 510. The shadowing of the tapered angle, θ, provides for evaporation deposition of an OLED material 112 and a cathode 114. The OLED material 112 may include one or more of a HIL, a HTL, an EML, and an ETL. The OLED material 112 is disposed over and in contact with the anode 104. The OLED material 112 is disposed under overhang extensions and may contact a tapered sidewall 515 of the tapered structures 510. In one embodiment, the OLED material 112 is different from the material of the tapered structures 510. The cathode 114 is disposed over the OLED material 112 and extends under the upper tapered structure surface 511. The cathode 114 may extend past an endpoint of the OLED material 112. The cathode 114 may contact the tapered sidewall 515 of the tapered structures 510. The tapered structures 510 and an evaporation angle set by an evaporation source define deposition angles, e.g., the overhang structures provide for a shadowing effect during evaporation deposition with the evaporation angle set by the evaporation source.

The cathode 114 includes a conductive material, such as a metal, e.g., the cathode 114 includes, but is not limited to, silver, magnesium, chromium, titanium, aluminum, ITO, or a combination thereof. In one embodiment, material of the cathode 114 is different from the material of the tapered structures 510. In some embodiments, the OLED material 112 and the cathode 114 are disposed over the tapered sidewall 515 of the tapered structures 510. In other embodiments, the OLED material 112 and the cathode 114 are disposed over an upper tapered structure surface 511 of the tapered structures 510. In still other embodiments, the OLED material 112 and the cathode 114 end on the tapered sidewall 515 of the tapered structures 510, e.g., are not disposed over the upper tapered structure surface 511 of the tapered structures 510.

The sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the tapered structures 510. The encapsulation layer 116 is disposed over the cathode 114 and extends at least to contact the cathode 114 over the tapered sidewall 515 of the tapered structures 510. In the illustrated embodiments as shown in FIG. 5, the encapsulation layer 116 extends to contact the tapered sidewall 515 of the tapered structures 510 and the upper tapered structure surface 511 of the tapered structures 510. In some embodiments, the encapsulation layer 116 extends to contact the tapered sidewall 515 of the tapered structures 510 and to be disposed over the OLED material 112 and the cathode 114 when the OLED material 112 and the cathode 114 are disposed over the contact the tapered sidewall 515 of the tapered structures 510, and the upper tapered structure surface 511 of the tapered structures 510. In some embodiments, the encapsulation layer 116 ends at the tapered sidewall 515 of the tapered structures. The encapsulation layer 116 includes the non-conductive inorganic material, such as the silicon-containing material. The silicon-containing material may include Si₃N₄ containing materials.

The OLED material 112 is disposed over and in contact with the anode 104. The cathode 114 is disposed over the OLED material 112. The encapsulation layer 116 is disposed over the cathode 114. The OLED material 112, the cathode 114, and the encapsulation layer 116 maintain continuity in order to apply current across each sub-pixel 106.

In embodiments including one or more capping layers, the capping layers are disposed between the cathode 114 and the encapsulation layer 116, e.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the sub-pixel circuit 500 further includes at least a global passivation layer disposed over the tapered structure 510 and the encapsulation layer 116. In yet another embodiment, the sub-pixel includes an intermediate passivation layer disposed over the tapered structures 510 of each of the sub-pixels 106, and disposed between the encapsulation layer 116 and the global passivation layer.

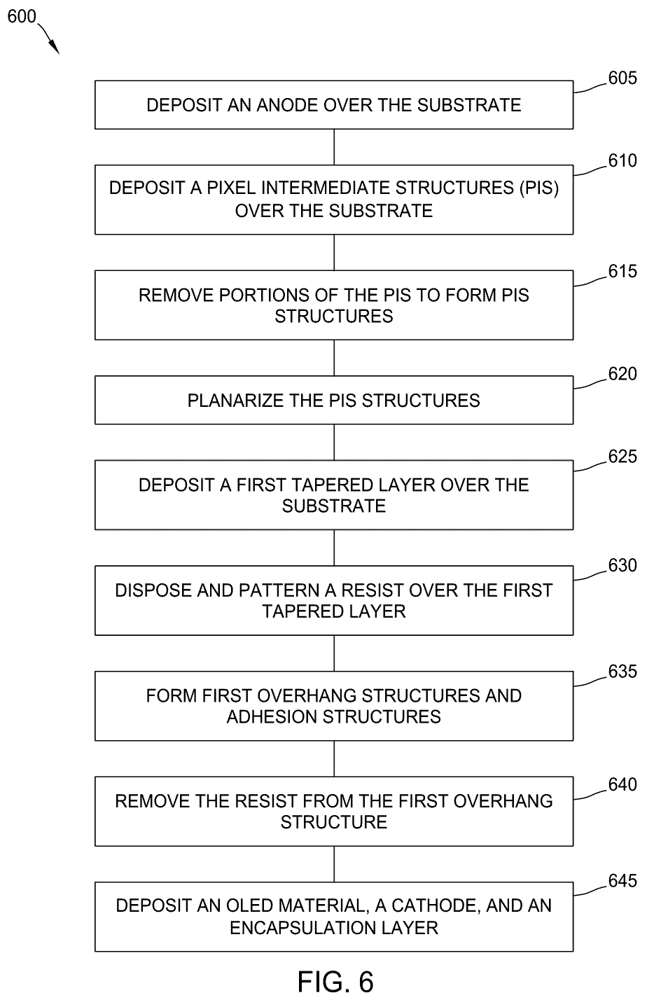

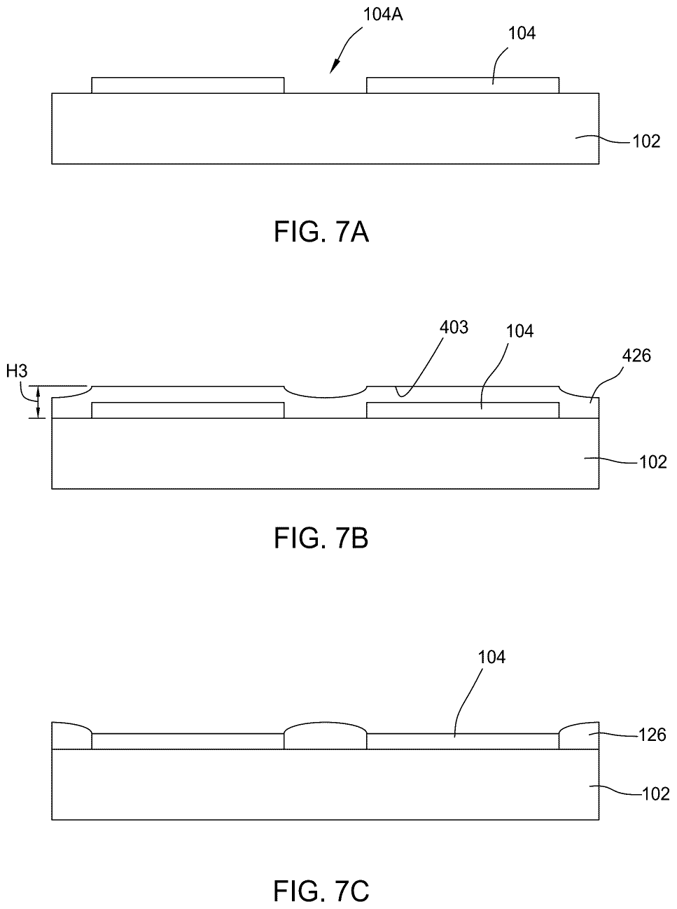

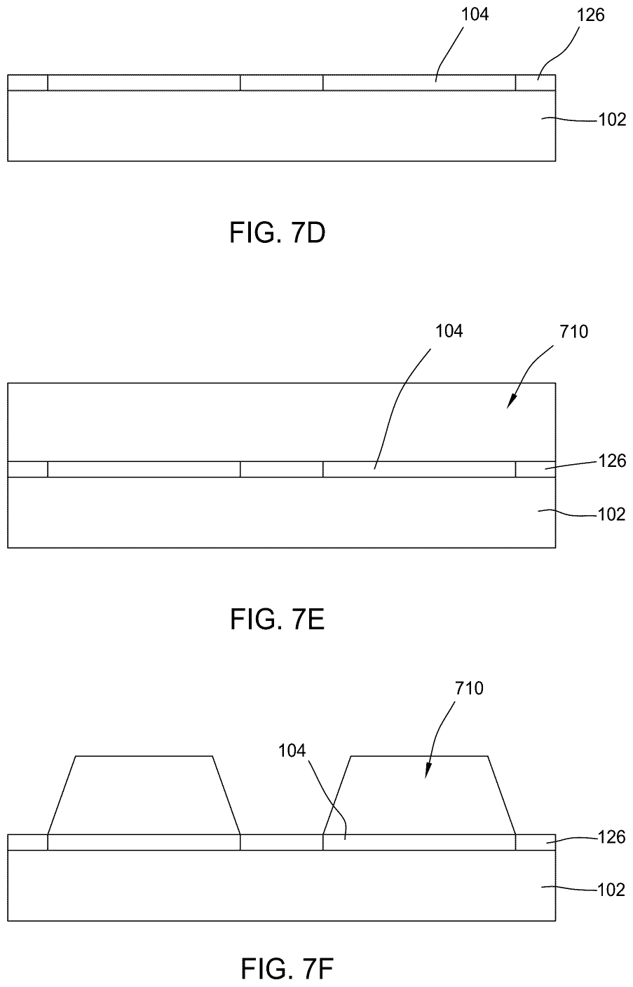

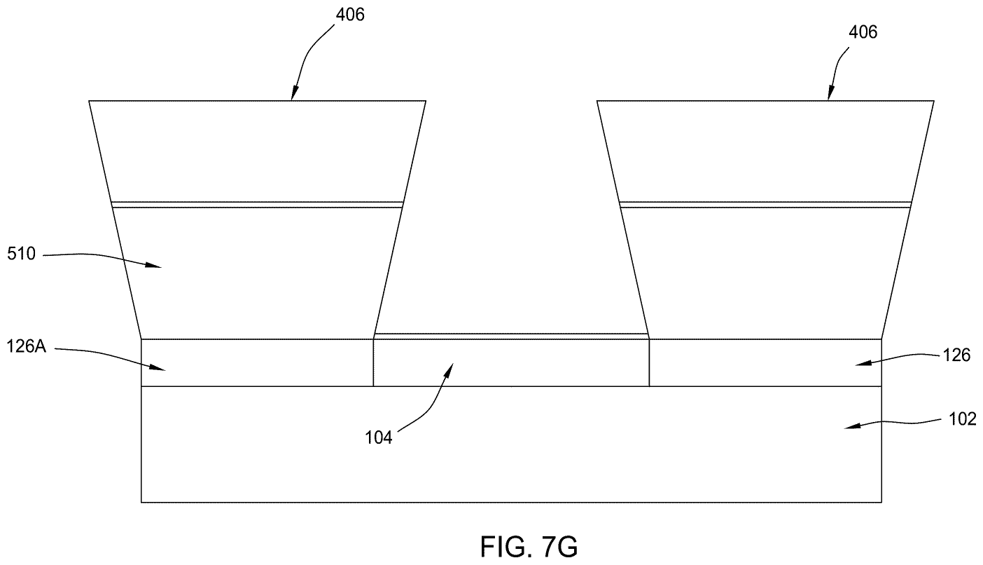

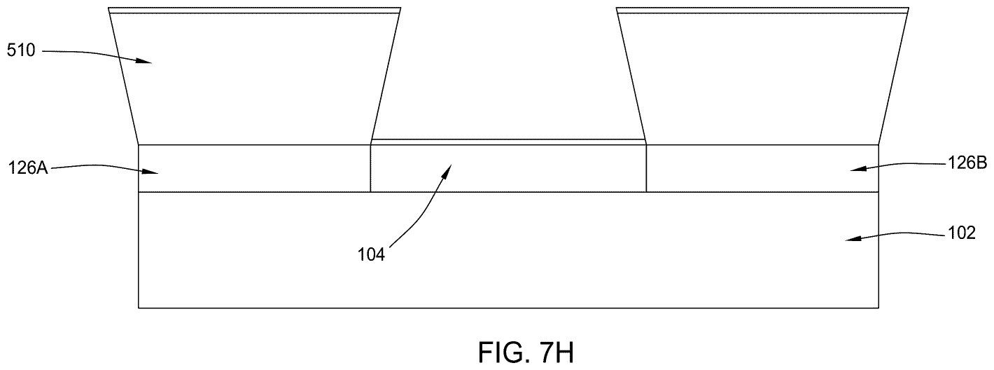

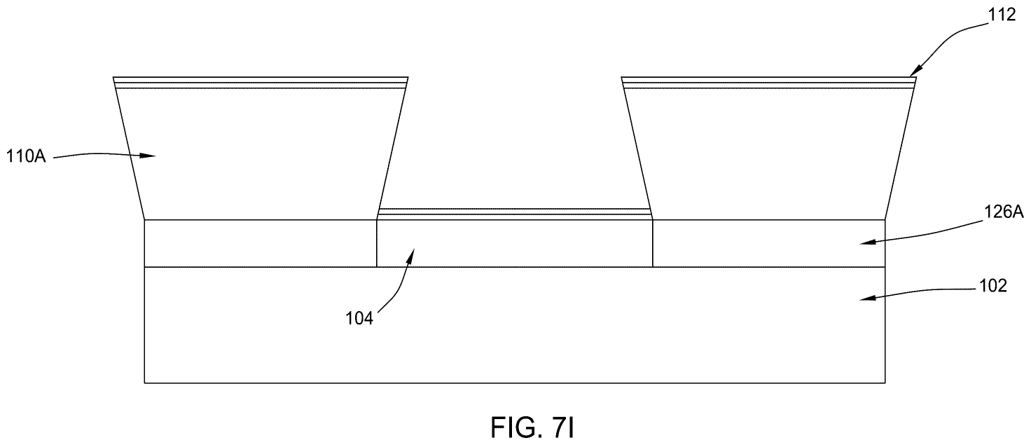

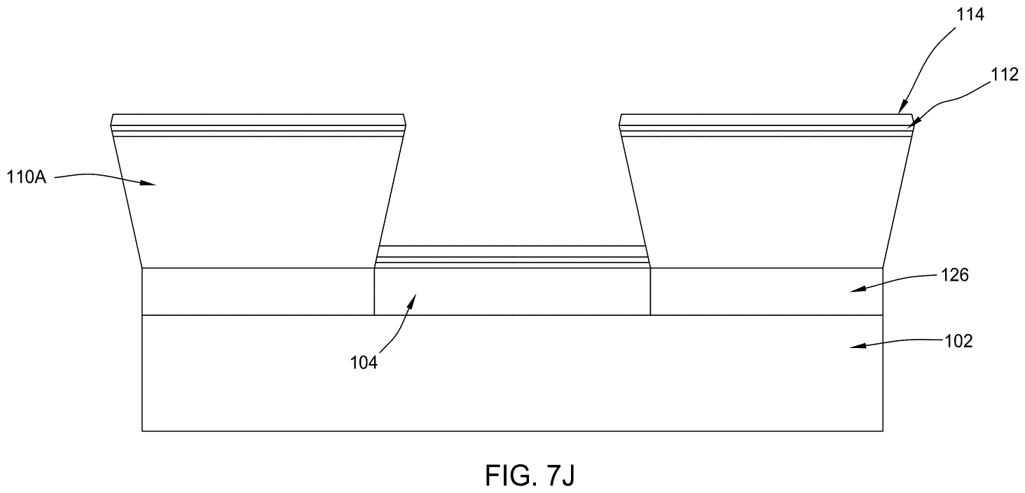

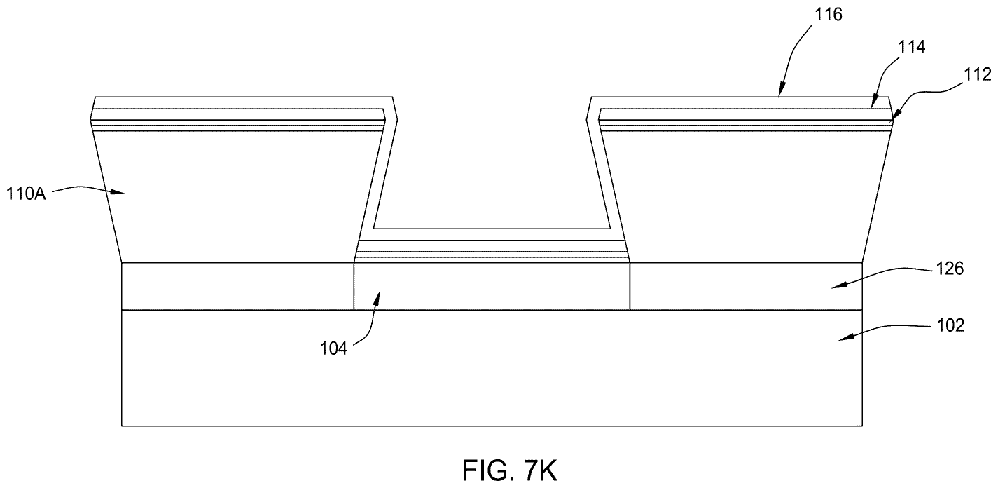

FIG. 6 is a flow diagram of a method 600 for forming a sub-pixel circuit 500 according to embodiment. FIG. 7A-7D are schematic, cross-sectional views of a substrate 102 during a method 600 for forming a sub-pixel circuit 500 according to embodiments described herein.

At operation 605, as shown in FIG. 7A, an anode 104 is deposited over the substrate 102, as shown in FIG. 7A. The anode 104 may be deposited on the substrate 102. In another embodiment, the anode 104 is deposited on a base layer. The base layer may be disposed on the substrate 102. The anode 104 may be deposited using metal-organic decomposition (MOD). An anode gap 104A separates each anode 104 from an adjacent anode.

At operation 610, as shown in FIG. 7B, a PIS layer 426 is deposited over the substrate 102. The PIS layer 426 may be deposited on the anode 104 and on the substrate 102 in the anode gap 104A. A height H3 from the substrate 102 to an upper surface 403 of the PIS layer 426 is from about 100 nm to about 700 nm.

At operation 615, as shown in FIG. 7C, portions of the PIS layer 426 are removed. The PIS layer 426 may be removed by a wet etch or dry etch process. Operation 615 exposes the anode 104 and forms a plurality of pixel isolation structures (PIS) 126, e.g., a first PIS and a second PIS. At operation 620, as shown in FIG. 7D, the PIS 126 are planarized. The upper surface of the PIS 126 are aligned with the upper surface of the anode 104. The PIS 126 are cured at a temperature of about 140° C. to about 180° C. for about 10 minutes to about 20 minutes. The curing of the PIS 126 enables shrinkage of the PIS 126. The PIS 126 are planarized after curing. The planarization process of the PIS 126 may be performed using chemical-mechanical planarization (CMP).

At operation 625, as shown in FIG. 7E, a tapered structure layer 710 is deposited over the substrate 102. The tapered structure layer 710 is deposited on the anode 104 and the PIS 126. The tapered structure layer 710 has a thickness t₁ from about 0.1 μm to about 0.5 μm.

At operation 630, as shown in FIG. 7F (along the pixel plane), a resist 406 is disposed and patterned. The resist 406 is disposed over the tapered structure layer 710. The resist 406 may have a width W₄ of about 0.8 μm to about 1.2 μm. The resist is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist 406 determines whether the resist is a positive resist or a negative resist. The portion of the tapered structure layer 710 that has the resist 406 disposed thereon is patterned to form a pixel opening 124 of a first sub-pixel. The patterning is one of a photolithography, digital lithography process, or laser ablation process.

At operation 635, as shown in FIG. 7G, first tapered structures are formed by removing portions of the tapered structure layer 710 exposed by the pixel opening 124. The tapered structure layer 710 is removed by ion beam milling. Operation 635 forms the tapered structures 510. At operation 640, as shown in FIG. 7H (along the pixel plane), the resist 406 is removed from the tapered structures 510.

At operation 645, as shown in FIGS. 71 and 7J, the OLED material 112 and the cathode 114 are deposited. The OLED material 112 includes an HIL material. The shadowing of the adjacent overhangs 109 provides for evaporation deposition of each of the OLED material 112 and the cathode 114. The OLED material 112 and the cathode 114 may separate (e.g., may be non-continuous) along the pixel plane. The OLED material 112 and cathode 114 maintain continuity along the line plane, e.g., the OLED material 112 and the cathode 114 are disposed over the PIS 126 and/or the anode 104. The total thickness of the OLED material 112 and the cathode 114 is from about 100 nm to about 150 nm.

Operation 645 includes depositing the encapsulation layer 116, as shown in FIG. 7K. The encapsulation layer 116 is deposited over the cathode 114. A thickness of the encapsulation layer is from about 10 nm to about 50 nm. The shadowing of the adjacent overhangs 109 provides for evaporation deposition of the encapsulation layer 116. The encapsulation layer 116 may maintain continuity along the pixel plane and the line plane.

Operations 605 to 645 may be repeated until the desired number of sub-pixels are formed.

Overall, a device is disclosed. The device includes a plurality of sub-pixel lines. Each sub-pixel line includes at least a first sub-pixel and a second sub-pixel. The first sub-pixel and the second sub-pixel each include an anode, overhang structures, separation structures, an organic light emitting diode (OLED) material, and a cathode. The overhang structures have inorganic upper portions and inorganic lower portions to allow for enhanced etch selectivity as well as reduced critical dimensions, e.g., about 1 nm to about 500 nm, between adjacent overhang structures. The overhang structures can allow for about 6000 pixels per inch (ppi) in a display.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel, comprising:
a plurality of pixel structures separating a plurality of anodes, the plurality of pixel structures disposed over a substrate;
a plurality of overhang structures disposed over the plurality of pixel structures, each overhang structure of the plurality of overhang structures comprising an upper portion comprising amorphous silicon disposed over a lower portion comprising germanium, wherein a bottom surface of the upper portion extends laterally past an upper surface of the lower portion; and
an organic light emitting diode (OLED) material disposed over an upper surface of the plurality of anodes and an upper surface of the plurality of pixel structures; and
a cathode disposed over the OLED material and the upper surface of the plurality of pixel structures.

2. The sub-pixel of claim 1, wherein the lower portion comprises a height from about 0.1 μm to about 0.5 μm.

3. The sub-pixel of claim 1, wherein the upper portion comprises a height of about 0.15 μm to about 0.25 μm.

4. The sub-pixel of claim 1, wherein the plurality of overhang structures comprise a distance of less than 0.15 μm from a first underside edge of the upper portion to a sidewall of the lower portion.

5. The sub-pixel of claim 1, wherein the bottom surface of the upper portion comprises a first width of about 0.4 μm to about 1.2 μm and the upper surface of the lower portion comprises a width of about 0.2 μm to about 0.8 μm.

6. A sub-pixel, comprising:
a plurality of pixel structures separating a plurality of anodes, the plurality of pixel structures disposed over a substrate;
a plurality of overhang structures disposed over the plurality of pixel structures, each overhang structure of the plurality of overhang structures comprising an upper portion comprising gallium arsenide disposed over a lower portion comprising amorphous silicon, wherein a bottom surface of the upper portion extends laterally past an upper surface of the lower portion; and
an organic light emitting diode (OLED) material disposed over an upper surface of the plurality of anodes and an upper surface of the plurality of pixel structures; and
a cathode disposed over the OLED material and the upper surface of the plurality of pixel structures.

7. The sub-pixel of claim 6, wherein the lower portion comprises a height from about 0.1 μm to about 0.5 μm.

8. The sub-pixel of claim 6, wherein the upper portion comprises a height of about 0.15 μm to about 0.25 μm.

9. The sub-pixel of claim 6, wherein the plurality of overhang structures comprise a distance of less than 0.15 μm from a first underside edge of the upper portion to a sidewall of the lower portion.

10. The sub-pixel of claim 6, wherein the bottom surface of the upper portion comprises a first width of about 0.4 μm to about 1.2 μm and the upper surface of the lower portion comprises a width of about 0.2 μm to about 0.8 μm.

11. A sub-pixel, comprising:
a plurality of pixel structures separating a plurality of anodes, the plurality of pixel structures disposed over a substrate;
a plurality of overhang structures disposed over the plurality of pixel structures, each overhang structure of the plurality of overhang structures comprising an upper portion comprising germanium disposed over a lower portion comprising silicon nitride, wherein a bottom surface of the upper portion extends laterally past an upper surface of the lower portion; and
an organic light emitting diode (OLED) material disposed over an upper surface of the plurality of anodes and an upper surface of the plurality of pixel structures; and
a cathode disposed over the OLED material and the upper surface of the plurality of pixel structures.

12. The sub-pixel of claim 11, wherein the lower portion comprises a height from about 0.1 μm to about 0.5 μm.

13. The sub-pixel of claim 11, wherein the upper portion comprises a height of about 0.15 μm to about 0.25 μm.

14. The sub-pixel of claim 11, wherein the plurality of overhang structures comprise a distance of less than 0.15 μm from a first underside edge of the upper portion to a sidewall of the lower portion.

15. The sub-pixel of claim 11, wherein the bottom surface of the upper portion comprises a first width of about 0.4 μm to about 1.2 μm and the upper surface of the lower portion comprises a width of about 0.2 μm to about 0.8 μm.

16. A sub-pixel, comprising:
a plurality of pixel structures separating a plurality of anodes, the plurality of pixel structures disposed over a substrate;
a plurality of overhang structures disposed over the plurality of pixel structures, each overhang structure of the plurality of overhang structures comprising an upper portion comprising gold disposed over a lower portion comprising amorphous silicon or silicon nitride, wherein a bottom surface of the upper portion extends laterally past an upper surface of the lower portion; and
an organic light emitting diode (OLED) material disposed over an upper surface of the plurality of anodes and an upper surface of the plurality of pixel structures; and
a cathode disposed over the OLED material and the upper surface of the plurality of pixel structures.

17. The sub-pixel of claim 16, wherein the lower portion comprises amorphous silicon.

18. The sub-pixel of claim 16, wherein the lower portion comprises silicon nitride.

19. The sub-pixel of claim 6, wherein the lower portion comprises a height from about 0.1 μm to about 0.5 μm, and wherein the upper portion comprises a height of about 0.15 μm to about 0.25 μm.

20. The sub-pixel of claim 16, wherein:
the plurality of overhang structures comprise a distance of less than 0.15 μm from a first underside edge of the upper portion to a sidewall of the lower portion, and
the bottom surface of the upper portion comprises a first width of about 0.4 μm to about 1.2 μm and the upper surface of the lower portion comprises a width of about 0.2 μm to about 0.8 μm.
